(19) United States
(12) Patent Application Publication
(10) Pub. No.: US 2014/0159153 A1
(43) Pub. Date: Jun. 12, 2014

(54) RF LDMOS DEVICE AND METHOD OF FORMING THE SAME

(71) Applicant: SHANGHAI HUAHONG GRACE SEMICONDUCTOR MANUFACTURING CORPORATION, Shanghai (CN)

(72) Inventor: Wensheng QIAN, Shanghai (CN)

(73) Assignee: SHANGHAI HUAHONG GRACE SEMICONDUCTOR MANUFACTURING CORPORATION, Shanghai (CN)

(21) Appl. No.: 14/099,171

(22) Filed: Dec. 6, 2013

(30) Foreign Application Priority Data
Dec. 7, 2012 (CN) 201210521428.1

(51) Int. Cl. H01L 29/49; H01L 29/66; H01L 29/78

(52) U.S. Cl. CPC H01L 29/4983; H01L 29/7816; H01L 29/66681
USPC 257/343; 438/306

(57) ABSTRACT

A radio frequency (RF) laterally diffused metal oxide semiconductor (LDMOS) device is disclosed, which includes: a gate structure on a surface of a substrate; and a source region and a drain region beneath the surface of the substrate, the source region and the drain region formed on opposite sides of the gate structure, wherein the gate structure includes a first section proximal to the source region and a second section proximal to the drain region, and wherein the first section of the gate structure has a dopant concentration at least one decimal order higher than a dopant concentration of the second section of the gate structure. A method of forming an RF LDMOS device is also disclosed. With the gate structure including two sections having different dopant concentrations, the present invention is capable of reducing the hot carrier injection effect while possessing a low on-resistance.

### CROSS-REFERENCES TO RELATED APPLICATIONS

This application claims the priority of Chinese patent application number 201210521428.1, filed on Dec. 7, 2012, the entire contents of which are incorporated herein by reference.

### TECHNICAL FIELD

The present invention relates generally to semiconductor devices, and in particular, to a laterally diffused metal oxide semiconductor (LDMOS) device usable in radio frequency (RF) applications.

### BACKGROUND

RF LDMOS devices are commonly used in RF base stations and RF broadcast stations. Manufacturers are always pursuing RF LDMOS devices having a high breakdown voltage, low on-resistance and low parasitic capacitance.

FIG. 1 shows an existing RF LDMOS device, which can be either a P-channel or N-channel one. In the case of an N-channel RF LDMOS device, as illustrated in FIG. 1, the reference number 1 represents a heavily-doped P-type substrate whereon a lightly-doped P-type epitaxial layer 2 is formed. In the lightly-doped P-type epitaxial layer 2, there is sequentially formed a heavily-doped N-type source region 8, a P-type channel region 7 and an N-type drift region 3, in this order in a side-by-side manner, with a heavily-doped N-type drain region 9 formed in the N-type drift region 3. The P-type channel region 7 and the N-type drift region 3 are overlaid by a gate oxide layer 4 and a uniformly-doped polysilicon gate electrode 5 and stacked in the order from the bottom up. The polysilicon gate electrode 5 and a portion of the N-type drift region 3 are covered by a silicon oxide layer 10, and a portion of the silicon oxide layer 10 is further covered by a gate shield layer 11 which extends above at least a portion of the N-type drift region 3 while being isolated by the silicon oxide layer 10. A sinker region 12 extends downwards from a surface of the source region 8, through the source region 8 and the epitaxial layer 2, into the substrate 1.

In the existing RF LDMOS device, the gate shield layer 11 is generally fabricated from metal or heavily-doped N-type polysilicon and can hence cause a reduced surface field (RESURF) effect which is capable of effectively increasing the breakdown voltage and effectively reducing the gate-drain parasitic capacitance of the device, thereby allowing the N-type drift region 3 to be relatively heavily doped to decrease the on-resistance of the device.

However, a high dopant concentration of the N-type drift region 3 may also lead to some consequences detrimental to the reliability of the device, in particular the intensification of the so-called hot carrier injection (HCI) effect. What can intensify the HCI effect is the strengthening of an originally high transverse electric filed in the N-type drift region 3 caused by the dopant concentration increase therein in the even of a high voltage being applied on the heavily-doped N-type drain region 9.

One way of improving the HCI effect is by increasing the thickness of the gate oxide layer 4, but this will also lead to an increase in the on-resistance of the device. Another way is to lower the dopant concentration of the N-type drift region 3. However, this approach will decrease the on-resistance of the device. Furthermore, while making a step-shaped gate oxide layer 4 whose thickness is larger in one section proximal to the drain region 9 than in the other section near to the source region 8 can enable an unchanged on-resistance of the device even when the N-type drift region 3 is heavily doped, such a complex structure of the step-shaped gate oxide layer 4 will increase the complexity of the fabrication process.

### SUMMARY OF THE INVENTION

The invention seeks to provide an RF LDMOS device that can be easily manufactured and is capable of mitigating the HCI effect while not increasing the on-resistance. The invention also seeks to provide a method of forming such an RF LDMOS device.

In a first aspect of the invention, there is provided an RF LDMOS device including: a gate structure on a surface of a substrate; and a source region and a drain region beneath the surface of the substrate, the source region and the drain region formed on opposite sides of the gate structure, wherein the gate structure includes a first section proximal to the source region and a second section proximal to the drain region, and wherein the first section of the gate structure has a dopant concentration at least one decimal order higher than a dopant concentration of the second section of the gate structure.

In a preferred embodiment, each of the first section and the second section may have a width equal to half of a width of the gate structure.

In a preferred embodiment, the first section of the gate structure may be heavily doped with a dopant concentration of 1×10²⁰ atoms/cm³ to 1×10²¹ atoms/cm³, while the second section of the gate structure may be moderately doped with a dopant concentration of 1×10¹⁸ atoms/cm³ to 1×10¹⁹ atoms/cm³.

In a second aspect of the invention, there is provided a method of forming an RF LDMOS device. The method includes the steps of: forming a gate structure on a surface of a substrate and forming a source region and a drain region beneath the surface of the substrate, wherein the source and drain regions are formed on opposite sides of the gate structure; and doping the gate structure to make a first section of the gate structure proximal to the source region have a dopant concentration at least one decimal order higher than a dopant concentration of a second section of the gate structure proximal to the drain region.

In a preferred embodiment, doping the gate structure may include: performing a first doping process on both of the first section and the second section; and covering the second section with a photoresist and performing a second doping process only on the first section to make the first section have a dopant concentration at least one decimal order higher than a dopant concentration of the second section.

In a preferred embodiment, the first doping process may be performed prior to the second doping process and after forming the gate structure.

In a preferred embodiment, the first doping process may be an in-situ doping process performed during forming the gate structure.

With the gate structure containing two sections having different dopant concentrations, the RF LDMOS device of the present invention has several advantages over those of the prior art.

For example, heavily doping the first section of the gate structure that is proximal to the source region leads to a maximum inhibition of polysilicon depletion.

Additionally, moderately doping the second section that is in proximity to the drain region allows for the occurrence of a certain amount of polysilicon depletion upon the application of a backward biasing voltage on the gate structure. This can lead to an increase in an equivalent gate oxide thickness in a vicinity of the drain region, which will facilitate electric field reduction in the channel region and hence mitigate the HCI effect therein in the normal bias state.

### BRIEF DESCRIPTION OF THE DRAWINGS

FIG. 1 is a schematic illustration of an RF LDMOS device of the prior art.

FIGS. 2a to 2i schematically illustrate a method of forming an RF LDMOS device in accordance with a first embodiment of the present invention.

FIGS. 3a to 3i schematically illustrate a method of forming an RF LDMOS device in accordance with a second embodiment of the present invention.

FIG. 4a depicts a dopant concentration gradient in the polysilicon gate structure of an RF LDMOS device constructed in accordance with the present invention along the direction from the source-proximal end of the polysilicon gate to the drain-proximal end thereof.

FIG. 4b shows widths of depletion regions of the two sections of the RF LDMOS device of FIG. 4a.

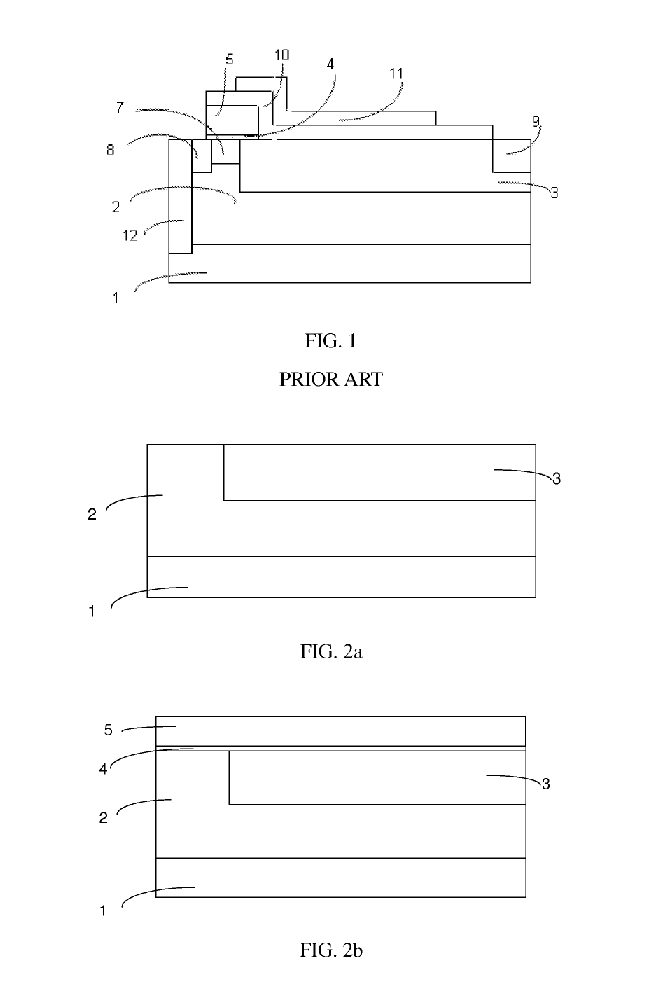

### DETAILED DESCRIPTION

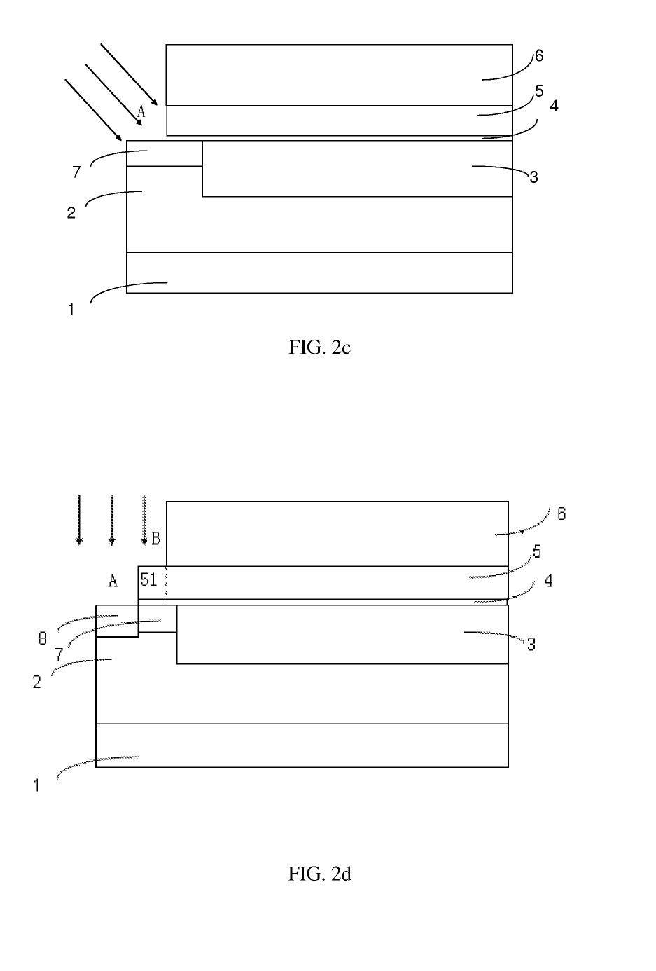

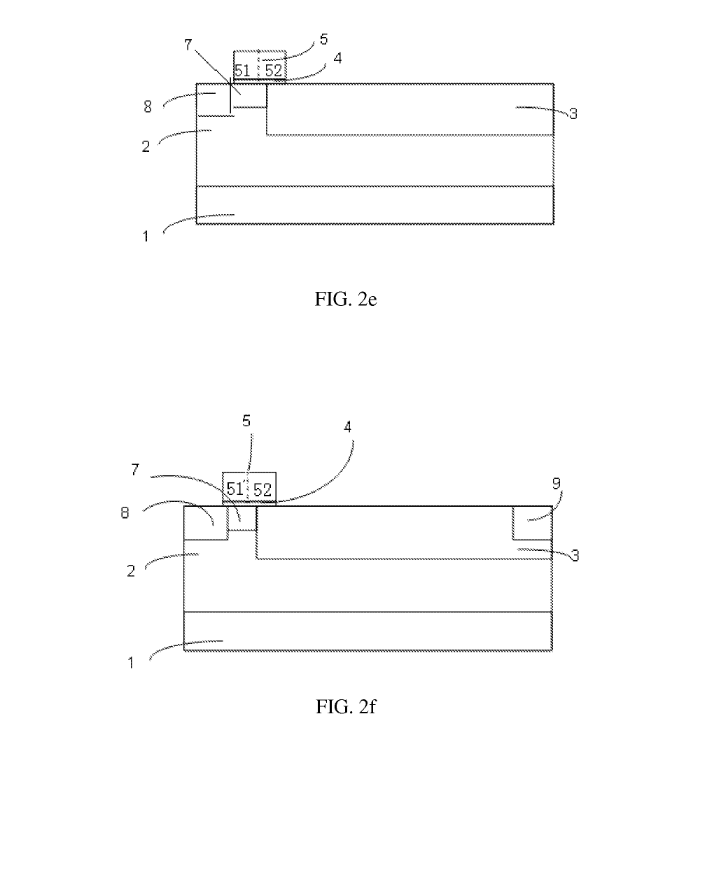

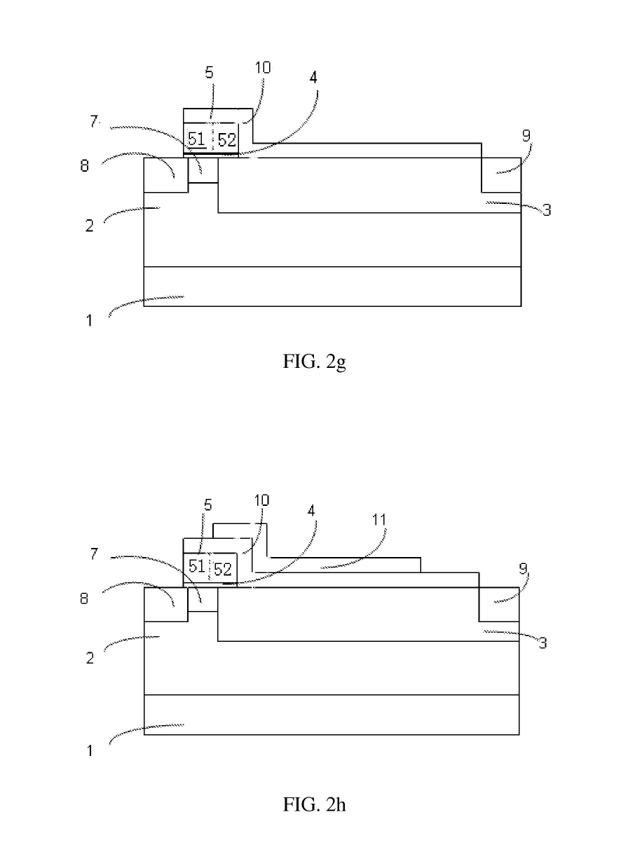

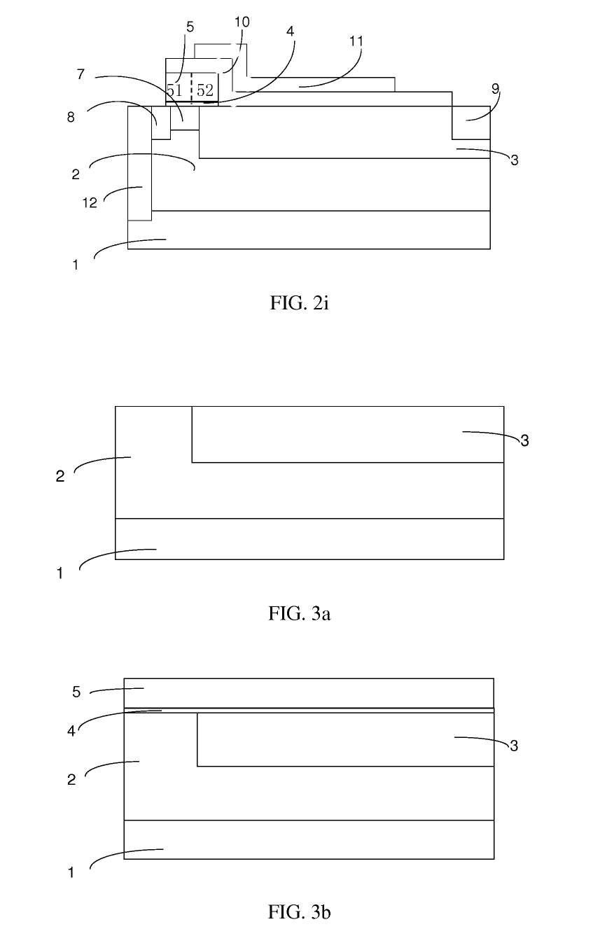

FIG. 2i is a schematic illustrating a radio frequency (RF) laterally diffused metal oxide semiconductor (LDMOS) device constructed in accordance with the present invention, which may be either a P-channel device or an N-channel device. In one embodiment, as illustrate in FIG. 2i, the RF LDMOS device is an N-channel device including a heavily-doped P-type substrate 1 and a lightly-doped P-type epitaxial layer 2 formed thereon. In the lightly-doped P-type epitaxial layer 2, there are sequentially formed side by side a heavily-doped N-type source region 8, a P-type channel region 7 and an N-type drift region 3 in this order, with a heavily-doped N-type drain region 9 formed in the N-type drift region 3. The P-type channel region 7 and the N-type drift region 3 are overlaid by a gate oxide layer 4 and a polysilicon gate structure 5 stacked from the bottom up. The polysilicon gate structure 5 and a portion of the N-type drift region 3 are covered by a continuous silicon oxide layer 10, and a portion or the whole of the silicon oxide layer 10 is further covered by a continuous gate shield layer 11 which extends above at least a portion of the N-type drift region 3 while being isolated by the silicon oxide layer 10. A sinker region 12 extends downwards from a surface of the source region 8, through the source region 8 and the epitaxial layer 2, into the substrate 1. Each of the source region 8, the sinker region 12, the polysilicon gate structure 5 and the drain region 9 is covered by a metal silicide. Alternatively, the source region 8 and the sinker region 12 may also be connected to external circuits through a metal on the backside of the substrate 1 instead.

As a variant, the N-channel RF LDMOS device may not include the epitaxial layer 2, and instead of that, other components of the device are directly formed in or on the substrate 1 accordingly.

In other embodiments, the RF LDMOS device of the present invention is a P-channel device which has a similar structure as that of the above described N-channel RF LDMOS device expect having components each with an opposite conductivity type to that of the counterpart of the N-channel device.

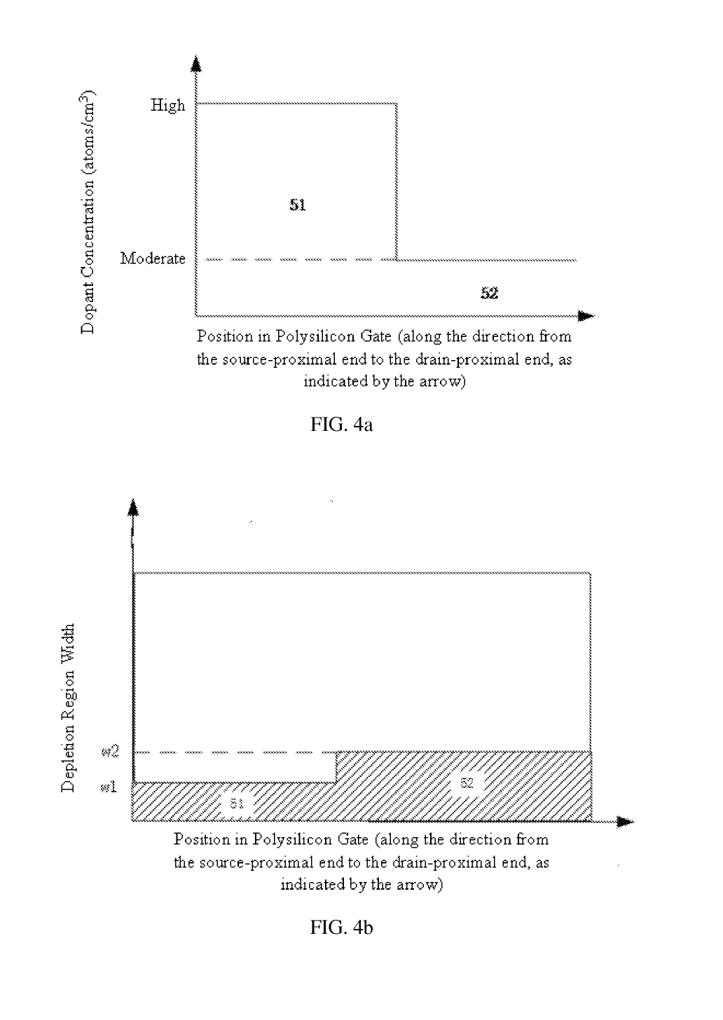

Regardless of the P-channel device or N-channel device, the polysilicon gate structure 5 consists of a first section 51 proximal to the source region 8 and a second section 52 proximal to the drain region 9. FIG. 4a depicts a dopant concentration gradient in the polysilicon gate structure 5 along the direction from the end thereof proximal to the source region 8 to the other end thereof proximal to the drain region 9. As can be observed in the figure, the polysilicon gate structure 5 is not uniformly doped, i.e., the first section 51 is heavily doped whilst the second section 52 is moderately doped, and a dopant concentration of the first section 51 is at least one decimal order higher than a dopant concentration of the second section 52. Preferably, the first section 51 is heavily doped with a dopant concentration of 1×10²⁰ atoms/cm³ to 1×10²¹ atoms/cm³ and the second section 52 is moderately doped with a dopant concentration of 1×10¹⁸ atoms/cm³ to 1×10¹⁹ atoms/cm³, respectively.

In a preferred embodiment, each of the first section 51 and the second section 52 has a width equal to half of a width of the polysilicon gate structure 5.

FIG. 4b shows widths of depletion regions of the first section 51 and the second section 52 of the RF LDMOS device of FIG. 4a. As illustrated, since the first section 51 proximal to the source region 8 is heavily doped, its depletion region width w1 is relatively small, which enables a maximum inhibition of the polysilicon depletion. Moreover, since the second section 52 proximal to the drain region 9 is moderately doped, it has a relatively large depletion region width w2, which allows for the occurrence of a certain amount of polysilicon depletion upon a backward biasing voltage being applied on the polysilicon gate structure 5 (the reason for this is because the depletion region width w2 is significantly larger than the depletion region width w1). This can lead to an increase in the equivalent gate oxide thickness in vicinity of the drain region 9, which will facilitate electric field reduction in the channel region and hence improving the HCI effect therein in a normal bias state (i.e., the state where a high voltage is applied on the drain region 9, with the polysilicon gate structure 5 being simultaneously applied with a turn-on biasing voltage).

The present invention also provides a method of forming an RF LDMOS device. By way of example, and not by way of limitation, the method is described in detail below in the context of the fabrication of an N-type RF LDMOS device.

In a first embodiment, the method includes the nine steps 1 to 9 as described below, which can be better understood when read in conjunction with FIGS. 2a to 2i.

In step 1, referring to FIG. 2a, a lightly-doped P-type epitaxial layer 2 is first formed over a heavily-doped P-type substrate 1, and thereafter a photolithography process using photoresist as a mask is performed, followed by one or more ion implantations, to form an N-type drift region 3 in the epitaxial layer 2.

As a variant, in step 1, forming the epitaxial layer 2 may be omitted, and accordingly, the drift region 3 and several other components as described below are formed directly in or on the substrate 1 instead.

In step 2, referring to FIG. 2b, a thermal oxidation process is employed to grow a silicon oxide layer 4 on a surface of the silicon material layer (including both the drift region 3 and a portion of the epitaxial layer 2), followed by depositing a polysilicon layer 5 over the entire surface of the silicon oxide layer 4. Next, ions of an N-type dopant are implanted in the polysilicon layer 5 at a moderate dose so that the polysilicon layer 5 is finally moderately-doped after the ion implantation. Preferably, the N-type dopant is phosphorus or arsenic implanted at a moderate dose of 1×10¹³ atoms/cm² to 1×10¹⁴ atoms/cm² and the polysilicon layer 5 has a moderate dopant concentration of 1×10¹⁸ atoms/cm³ to 1×10¹⁹ atoms/cm³.

As a variant, the N-type dopant may also be doped in an in-situ manner, during the deposition of the polysilicon layer 5, at a concentration of 1×10¹⁸ atoms/cm³ to 1×10¹⁹ atoms/cm³.

In step 3, referring to FIG. 2c, photolithography and etching processes are performed to form an opening A extending through both the polysilicon layer 5 and the silicon oxide layer 4 to expose a corresponding portion of the surface of the underlying epitaxial layer 2, leaving the remainder of the epitaxial layer 2 and the entire drift region 3 still covered by the remaining portions of the vertically stacked silicon oxide, polysilicon and photoresist layers 4, 5, 6. Subsequently, ions of a P-type dopant, which is preferred to be boron, are implanted through the opening A into the exposed portion of the epitaxial layer 2 to form a channel region 7 therein in contact with the drift region 3 side by side.

Preferably, the P-type ions are implanted with a certain inclination (as indicated by arrows) to facilitate the lateral extension of the channel region 7 under the silicon oxide layer 4 and in contact with the drift region 3.

In step 4, referring to FIG. 2d, a side portion of the photoresist layer 6 proximal to the opening A is removed to form an opening B closely adjacent to the opening A. After that, ions of an N-type dopant, which is preferred to be arsenic, are implanted both in the openings A, B using a source/drain implantation process to create a source region 8 right under the opening A and to cause a portion of the polysilicon layer 5 right under the opening B to have a high dopant concentration. As a result, the channel region 7 shrinks to a region sandwiched between the source region 8 and the drift region 3. In addition, except the portion right under the opening B, the dopant concentration of the rest of the polysilicon layer 5 remains at a moderate level.

Preferably, the N-type ions are perpendicularly implanted in the source/drain implantation process at a dose of 1×10¹⁵ atoms/cm² to 1×10¹⁶ atoms/cm² and the target regions 8 and 51 have a high dopant concentration of 1×10²⁰ atoms/cm³ to 1×10²¹ atoms/cm³.

Preferably, the opening B has a width equal to half of a width of a polysilicon gate structure 5 as described in detail below.

In step 5, referring to FIG. 2e, photolithography and etching processes are performed to shape the silicon oxide layer 4 and the polysilicon layer 5 into a gate oxide layer 4 and a polysilicon gate structure 5, respectively. The gate oxide layer 4 is formed with one portion overlying the channel region 7 and the other portion overlying the drift region 3. The polysilicon gate structure 5 consists of a heavily-doped first section 51 adjacent to the source region 8 and a moderately-doped second section 52.

In step 6, referring to FIG. 2f, ions of an N-type dopant are implanted in an end portion of the drift region 3 away from the gate oxide layer 4 using a source/drain implantation process to form therein a drain region 9. The source/drain implantation process may be performed at a dose of greater than 1×10¹⁵ atoms/cm².

In step 7, referring to FIG. 2g, another silicon oxide layer 10 is deposited over the surface of the whole structure resulting from the previous step. Next, portions of the silicon oxide layer 10 respectively overlying the source and drain regions 8, 9 are removed using photolithography and etching processes, leaving the remainder of the silicon oxide layer 10 continuously covering the polysilicon gate structure 5 and the drift region 3.

In step 8, referring to FIG. 2h, a metal layer is deposited over the surface of the entire resulting structure from the previous step, and then is shaped into a gate shield layer 11 using photolithography and etching processes. The gate shield layer 11 continuously covers a portion or the whole of the remainder of the silicon oxide layer 10, and covers at least a portion of the drift region 3 while being isolated by a corresponding portion of the silicon oxide layer 10.

Alternatively, the gate shield layer 11 may also be fabricated from heavily-doped N-type polysilicon, either by first depositing non-doped polysilicon and then implanting N-type ions therein, or by directly depositing heavily-doped N-type polysilicon (i.e., in an in-situ manner).

In step 9, referring to FIG. 2i, photolithography and etching processes are employed to form a “deep” hole extending from an upper surface of the source region 8, through the source region 8 and the epitaxial layer 2, and into the substrate 1. Next, a metal, preferably tungsten, is filled in the hole to form a sinker region 12. As a variant, a trench may be formed instead of the deep hole.

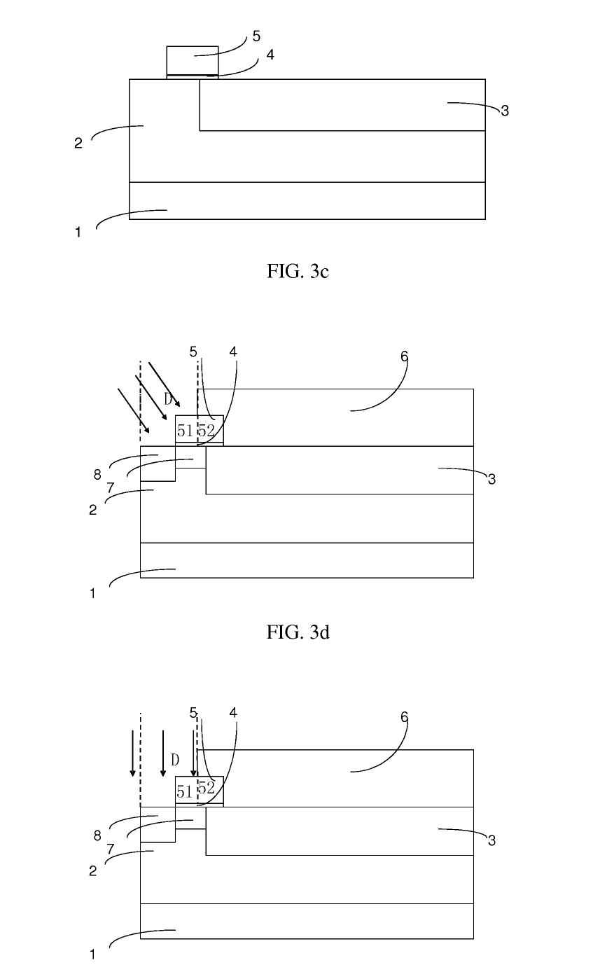

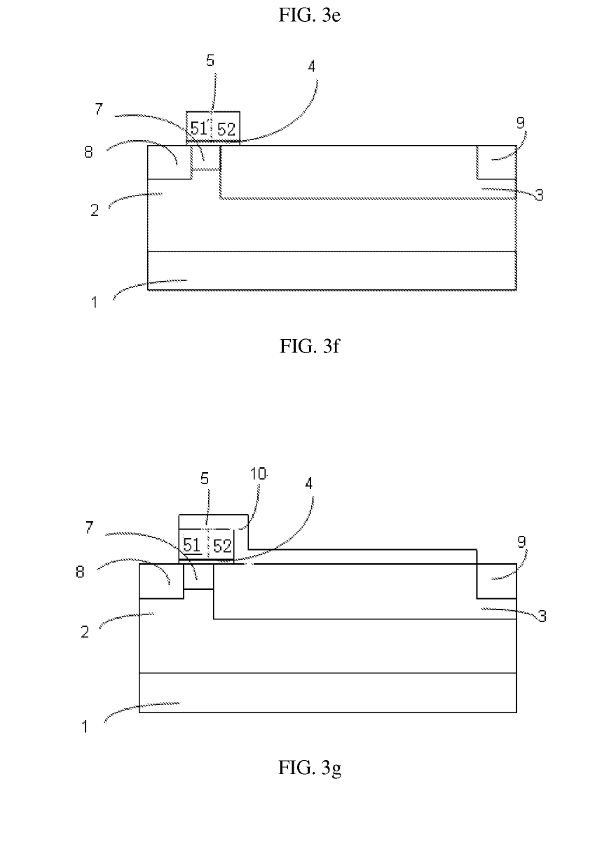

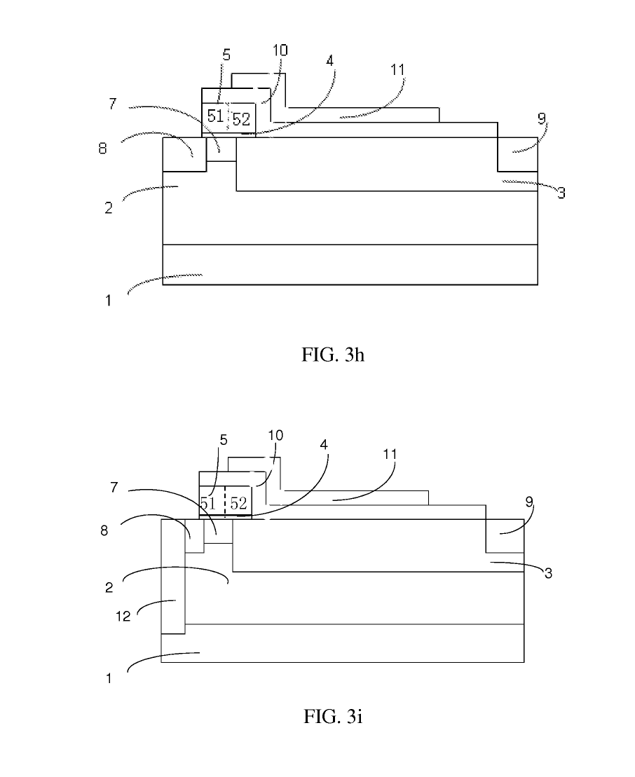

In a second embodiment, the method includes the following nine steps 1′ to 9′ as described below, which can be better understood by referencing FIGS. 3a to 3i.

As seen in FIGS. 3a and 3b, steps 1′ and 2′ of this embodiment are the same as the corresponding steps 1 and 2 of the first embodiment.

In step 3′, referring to FIG. 3c, photolithography and etching processes are performed to shape the silicon oxide layer and polysilicon layer into a gate oxide layer 4 and a polysilicon gate structure 5, respectively. The gate oxide layer 4 has a portion overlying the epitaxial layer 2 and the rest portion overlying the drift region 3.

In step 4′, referring to FIG. 3d, a photolithography process is performed to form, in a photoresist layer 6, an opening D exposing a portion of the epitaxial layer 2 on one side of the polysilicon gate structure 5 and a first section 51 of the polysilicon gate structure 5 away from the drift region 3, with a second section 52 of the polysilicon gate structure 5 proximal to the drift region 3 and the drift region 3 on the other side of the polysilicon gate structure 5 still being covered by the remainder of the photoresist layer 6. Next, ions of a P-type dopant, preferably boron, are implanted into the exposed portion of the epitaxial layer 2 using the remainder of the photoresist layer 6 and the second section 52 of the polysilicon gate structure 5 as a mask to form a channel region 7 laterally contacting with the drift region 3.

In this step, ions of the P-type dopant are also implanted into the exposed first section 51 of the polysilicon gate structure 5. However, given that this P-type ion implantation process is intended to form the P-type channel region 7 that has a dopant concentration much lower than the moderate dopant concentration of the N-doped polysilicon gate structure 5, and that the first section 51 will be further doped using N-type dopant to have a high N-type dopant concentration in the subsequent step 5′ as described below, the P-type ions implanted in this step is considered to have no impact on the intended characteristics of the first section 51 of the polysilicon gate structure 5.

Preferably, the P-type ions are implanted with a certain inclination (as indicated by arrows) to facilitate the lateral extension of the channel region 7 under the silicon oxide layer 4 and in contact with the drift region 3.

In step 5′, referring to FIG. 3e, a source/drain implantation process is employed to implant ions of an N-type dopant through the opening D, which is preferred to be arsenic, using the remainder of the photoresist layer 6 as a mask, thereby forming a source region 8 in the exposed portion of the epitaxial layer 2 and causing the exposed first section 51 of the polysilicon gate structure 5 to have a high N-type dopant concentration. As a result, the channel region 7 shrinks to a region sandwiched between the source region 8 and the drift region 3, and the second section 52 of the polysilicon gate structure 5 covered by the remainder of the photoresist layer 6 remains moderately-doped.

Preferably, the N-type ions are perpendicularly implanted in the source/drain implantation process at a dose of 1×10 ¹⁵ atoms/cm² to 1×10¹⁶ atoms/cm² and the first section 51 of the polysilicon gate structure 5 has a high dopant concentration of 1×10²⁰ atoms/cm³ to 1×10²¹ atoms/cm³.

Preferably, the first section 51 exposed in the opening D has a width equal to half of a width of the polysilicon gate structure 5.

In both the first and second embodiments, the method may further include subsequent steps of: depositing a metal layer over the whole resulting substrate; and annealing the structure at a high temperature to form metal silicide along where the metal layer comes in contact with silicon and polysilicon, i.e., top surfaces of the source region 8, the sinker region 12, the polysilicon gate structure 5, the gate shield layer 11 and the drain region 9. Alternatively, the source and sinker regions 8, 12 may also be connected to external circuits through a metal on the backside of the substrate.

In other embodiments, the method is employed to fabricate a P-channel RF LDMOS device by forming in the nine steps components similar to those of the above described embodiments except each having an opposite conductivity type. For example, in this embodiment, a heavily-doped N-type silicon substrate, optionally formed thereon with a lightly-doped N-type epitaxial layer is provided in step 1 or 1′; in step 2 or 2′, ions of a P-type dopant are implanted, with boron being preferred; in step 3 or 4′, ions of an N-type dopant are implanted, preferably phosphorus or arsenic; and in step 4 or 5′, ions of a P-type dopant are implanted, which is preferred to be boron.

Similarly, as can be seen from FIG. 4a, an RF LDMOS device fabricated using the method of the present invention has a non-uniformly doped polysilicon gate structure 5 consisting of a heavily-doped first section 51 and a moderately-doped second section 52. As described above, such structure leads to different depletion region widths w1 and w2 of the first and second sections 51 and 52, as shown in FIG. 4b, which enables the RF LDMOS device to have an improved HCI effect without increasing the on-resistance.

It is to be understood that the preferred embodiments of the present invention presented in the foregoing description are not intended to limit the invention in any way. Those skilled in the art can make various alterations, modifications, and equivalent alternatives without departing from the scope of the invention. Thus, it is intended that the present invention covers all such alterations, modifications, and equivalent alternatives that fall within the true scope of the invention.

What is claimed is:

1. A radio frequency (RF) laterally diffused metal oxide semiconductor (LDMOS) device comprising: a gate structure on a surface of a substrate; and a source region and a drain region beneath the surface of the substrate, the source region and the drain region formed on opposite sides of the gate structure, wherein the gate structure comprises a first section proximal to the source region and a second section proximal to the drain region, and wherein the first section of the gate structure has a dopant concentration at least one decimal order higher than a dopant concentration of the second section of the gate structure.

2. The RF LDMOS device of claim 1, wherein each of the first section and the second section has a width equal to half of a width of the gate structure.

3. The RF LDMOS device of claim 1, wherein the first section of the gate structure is heavily doped with a dopant concentration of 1×10²⁰ to 1×10²¹ atoms/cm³ and the second section of the gate structure is moderately doped with a dopant concentration of 1×10¹⁸ to 1×10¹⁹ atoms/cm³.

4. A method of forming a radio frequency (RF) laterally diffused metal oxide semiconductor (LDMOS) device comprising:
forming a gate structure on a surface of a substrate and forming a source region and a drain region beneath the surface of the substrate, wherein the source and drain regions are formed on opposite sides of the gate structure; and
doping the gate structure to make a first section of the gate structure proximal to the source region have a dopant concentration at least one decimal order higher than a dopant concentration of a second section of the gate structure proximal to the drain region.

5. The method of claim 4, wherein each of the first section and second section has a width equal to half of a width of the gate structure.

6. The method of claim 5, wherein doping the gate structure comprises:
performing a first doping process on both of the first section and the second section; and
covering the second section with a photoresist and performing a second doping process only on the first section to make the first section have a dopant concentration at least one decimal order higher than a dopant concentration of the second section.

7. The method of claim 6, wherein the first doping process is performed prior to the second doping process and after forming the gate structure.

8. The method of claim 6, wherein the first doping process is an in-situ doping process performed during forming the gate structure.

9. The method of claim 4, wherein the first section of the gate structure is heavily doped with a dopant concentration of 1×10²⁰ atoms/cm³ to 1×10²¹ atoms/cm³ and the second section of the gate structure is moderately doped with a dopant concentration of 1×10¹⁸ atoms/cm³ to 1×10¹⁹ atoms/cm³.
